(19) United States
(12) Patent Application Publication
(10) Pub. No.: US 2026/0229296 A1
(43) Pub. Date: Aug. 6, 2026

(54) ON-THE-FLY READ-LEVEL CALIBRATION FOR MEMORY SUB-SYSTEMS

(71) Applicant: Micron Technology, Inc., Boise, ID (US)

(72) Inventors: Gary F. Besinga, Boise, ID (US); Michael G. Miller, Boise, ID (US); Tawalin Opastrakoon, Boise, ID (US); Che Chen, Boise, ID (US)

(21) Appl. No.: 19/044,155

(22) Filed: Feb. 3, 2025

(51) Int. Cl. G11C 16/34

(52) U.S. Cl. CPC G11C 16/3404

(57) ABSTRACT

A processing device obtains calibration samples for a block of a memory device from a subset of pages of the block. The processing device determines one or more calibration offsets for the block based on the calibration samples from the subset of pages of the block. The processing device applies the one or more calibration offsets during one or more read operations performed on the block of the memory device.

### TECHNICAL FIELD

Embodiments of the disclosure relate generally to memory sub-systems and, more specifically, to techniques for performing on-the-fly read-level calibrations for memory sub-systems.

### BACKGROUND

A memory sub-system can be a storage system, such as a solid-state drive (SSD), and can include one or more memory components that store data. The memory components can be, for example, memory devices that include non-volatile memory components and/or volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system, in accordance with some examples.

FIG. 2 is a data flow diagram illustrating interactions between components in the memory sub-system in performing read-level calibrations on a memory device, in accordance with some examples.

FIGS. 3 and 4 are flow diagrams illustrating an example method for performing read-level calibrations on a memory device, in accordance with some examples.

FIG. 5 is a block diagram of an example computer system in which embodiments of the present disclosure may operate.

### DETAILED DESCRIPTION

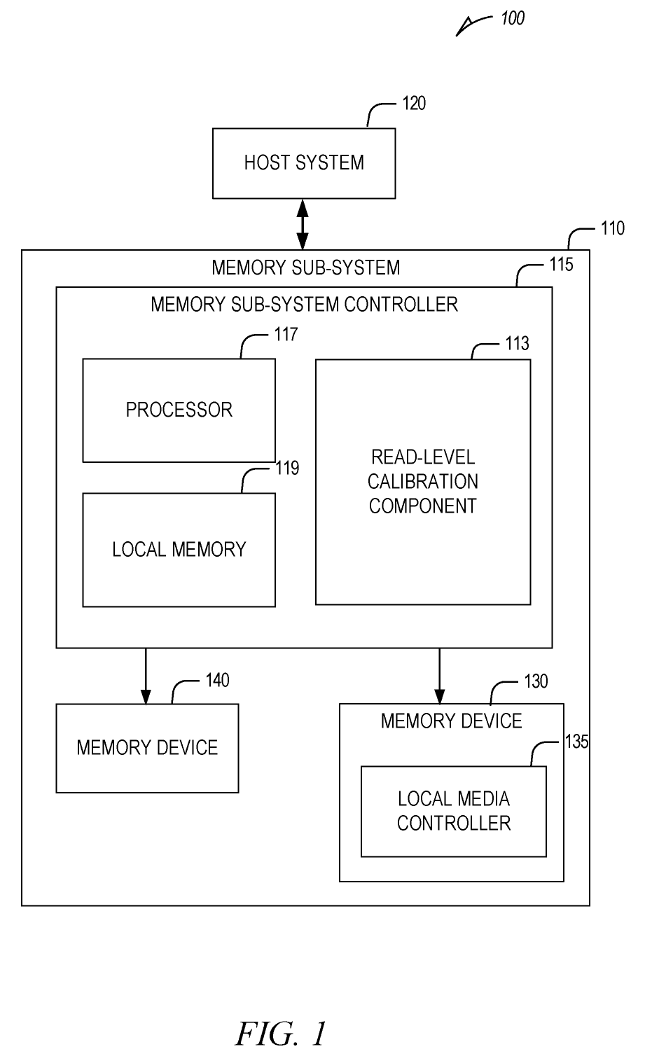

Aspects of the present disclosure are directed to an approach for performing read-level calibrations of a memory device in a memory sub-system. A memory sub-system can be or include a memory device (e.g., solid-state drive [SSD]), a memory module, or a combination of a memory device and memory module. Examples of memory devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system. A memory sub-system controller typically receives commands or operations from the host system and converts the commands or operations into instructions or appropriate commands to achieve the desired access to the memory components of the memory sub-system.

A memory device can be a non-volatile memory device. One example of a non-volatile memory device is a negative-and (NAND) memory device. A NAND memory device can include multiple NAND dies. Each die may include one or more planes, and each plane includes multiple blocks. Each block includes an array that includes pages (rows) and strings (columns). Pages may be organized into multiple groups such as wordline groups. A string includes a plurality of memory cells connected in series. A memory cell (also referred to herein simply as a “cell”) is an electronic circuit that stores information. Depending on the cell type, a cell can store one or more bits of binary information and has various logic states that correlate to the number of bits being stored. The logic states can be represented by binary values, such as “0” and “1,” or combinations of such values.

Various memory access operations can be performed on the memory cells. Data can be written to, read from, and erased from memory cells. Memory cells can be grouped into a write unit, such as a page. For some types of memory devices, a page is the smallest write unit. A page size represents a particular number of cells of a page. Data can be written to a block, page-by-page. During write operations, data is programmed into a block of the memory device using a programming sequence that includes multiple passes in which programming pulses are applied to cells in the block. Over the multiple passes, the programming pulses configure the threshold voltages (Vt) of the cells in each page according to the value that the cells are intended to represent. As the programming sequence progresses, the voltage level of the programming pulses increase until a target voltage level for each cell is reached.

The Vt distribution of a memory cell can be divided into a number of regions based on the number of bits stored by the cell where each region corresponds to a value that can be represented by the cell. More specifically, each region corresponds to a read-level, and each read-level decodes into a multi-bit value. For example, a TLC NAND flash cell can be at one of eight charge levels (L0, L1, L2, L3, L4, L5, L6, or L7) and each charge level decodes into a 3-bit value that is stored in the flash cell (e.g., 111, 110, 100, 000, 010, 011, 001, and 101). Generally, to read data from a memory cell, one or more read-level voltages are applied to the gate of a transistor (of the memory cell) to determine (e.g., sense) the value of the current threshold voltage (e.g., the voltage at which the transistor conducts current), and the current threshold voltage value can be decoded (e.g., mapped) to a data value (e.g., bit string) stored by the memory cell.

One of the key challenges to managing read operations in memory devices is handling Vt variations due to various factors such as word line-to-word line (WL/WL) variations and block-to-block variations. These variations can lead to read errors and performance degradation if not properly addressed.

To mitigate the impact of Vt variations, among other issues, read-level voltages of memory devices are regularly calibrated to maintain optimal performance and reliability. Read-level calibration is performed for memory devices to properly position read-levels between voltage distributions to minimize error rates and reduce the need for error recovery operations. Generally, read-level calibration involves determining calibration offsets for portions of the memory device based on one or more calibration samples to optimally position read-level voltages between voltage distributions to properly distinguish between different read-levels. A calibration offset for a particular portion of the memory device is then applied to a read-level voltage during read operations on the portion of the memory device.

Current calibration approaches in SSD systems generally fall into two categories. The first approach involves sampling a small subset of blocks within the memory device and applying those calibration values across all blocks. While this method provides relatively low latency during operation, it can result in reduced calibration accuracy due to variations that exist between different blocks in the memory device.

The second approach implements page-level calibration where every single page in the memory device is sampled to determine per-page calibration offsets. This method achieves the highest level of accuracy by individually calibrating each page. However, the comprehensive nature of this approach results in significantly increased read latency during system operation.

Aspects of the present disclosure address the above and other issues with a memory sub-system that performs selective page sampling across all blocks of a memory device in performing read-level calibration. This approach samples a subset of pages within each block rather than sampling all pages or limiting sampling to specific blocks. By sampling a subset of pages within each block rather than limiting sampling to specific blocks as with the first approach discussed above, this approach achieves better calibration accuracy while maintaining lower latency compared to full page-level calibration approach. What’s more, the selective sampling technique allows optimization based on performance characteristics, where pages sharing similar performance patterns can be represented by sampling one or two pages from each group.

A read-level calibration component (e.g., implemented by a memory sub-system controller) manages the calibration process, determining which pages to sample and how many pages to include in the subset. The number of pages in the subset can be adjusted based on system requirements. As an example, the read-level calibration component can select representative pages from wordline groups, as pages within the same wordline group often exhibit similar performance patterns.

The read-level calibration component determines calibration offsets based on the selective sampling. The calibration offsets obtained through sampling can be stored either in the memory device itself or in local memory of the read-level calibration component. When host read operations transition between blocks, the system can perform recalibration as needed. This allows for adaptation to changing conditions during operation.

In addition, performance characteristics can be tuned through adjustment of the sampling subset size, which is a configurable parameter. A larger subset of pages provides increased accuracy but requires additional processing time. Conversely, a smaller subset reduces latency while potentially affecting calibration precision. This allows for optimization based on specific system requirements.

The calibration process described herein operates proactively rather than waiting for errors to occur. By sampling pages across all blocks, the system maintains calibration values that account for variations between blocks. This differs from approaches that only calibrate in response to detected errors.

FIG. 1 illustrates an example computing environment 100 that includes a memory sub-system 110, in accordance with some embodiments of the present disclosure.

The memory sub-system 110 can include media, such as one or more volatile memory devices (e.g., memory device 140), one or more non-volatile memory devices (e.g., memory device 130), or a combination of such.

A memory sub-system 110 can be a memory device, a memory module, or a hybrid of a memory device and memory module. Examples of a memory device include an SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, and so forth.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize a Non-Volatile Memory Express (NVMe) interface to access the memory devices 130 and 140 when the memory sub-system 110 is coupled with the host system 120 by the PCIe or CXL interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130) includes a NAND type flash memory. Each of the memory devices 130 can include one or more arrays of memory cells such as single level cells (SLCs), multi-level cells (MLCs) (e.g., triple level cells [TLCs], or quad-level cells [QLCs]). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), NOR flash memory, electrically erasable programmable read-only memory (EEPROM), and a cross-point array of non-volatile memory cells. A cross-point array of non-volatile memory can perform bit storage based on a change of bulk resistance in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 115 can communicate with the memory devices 130 to perform operations such as reading data, writing data, or erasing data at the memory devices 130 and at other such operations. The memory sub-system controller 115 can include hardware such as one or more integrated circuits and/or discrete components, a buffer memory, or a combination thereof. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and the like. The local memory 119 can also include ROM for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 and convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

The memory sub-system 110 also includes a read-level calibration component 113 that is responsible for performing read-level calibrations on the memory device 130. More specifically, the read-level calibration component 113 obtains calibration samples (e.g., by performing one or more calibration read operations) for each block of the memory device 130 from a sub-set of pages of each block and determines one or more calibration offsets for each block based on the calibration samples obtained from the sub-set of pages of each block. The read-level calibration component 113 stores the calibration offsets for each block (e.g., in a dedicated portion of the memory device 130 or the local memory 119) and uses the corresponding calibration offset in read operations (e.g., by applying the calibration offset to a read voltage used during read operations).

In some embodiments, the memory sub-system controller 115 includes at least a portion of the read-level calibration component 113. For example, the memory sub-system controller 115 can include a processor 117 (processing device) configured to execute instructions stored in local memory 119 (e.g., firmware) for performing the operations described herein. In some embodiments, the read-level calibration component 113 is part of the host system 120, an application, or an operating system.

In some embodiments, the memory devices 130 include local media controllers 135 that operate in conjunction with memory sub-system controller 115 to execute operations on one or more memory cells of the memory devices 130. In some examples, the local media controllers 135 include at least a portion of the read-level calibration component 113. Further details regarding the read-level calibration component 113 are discussed below.

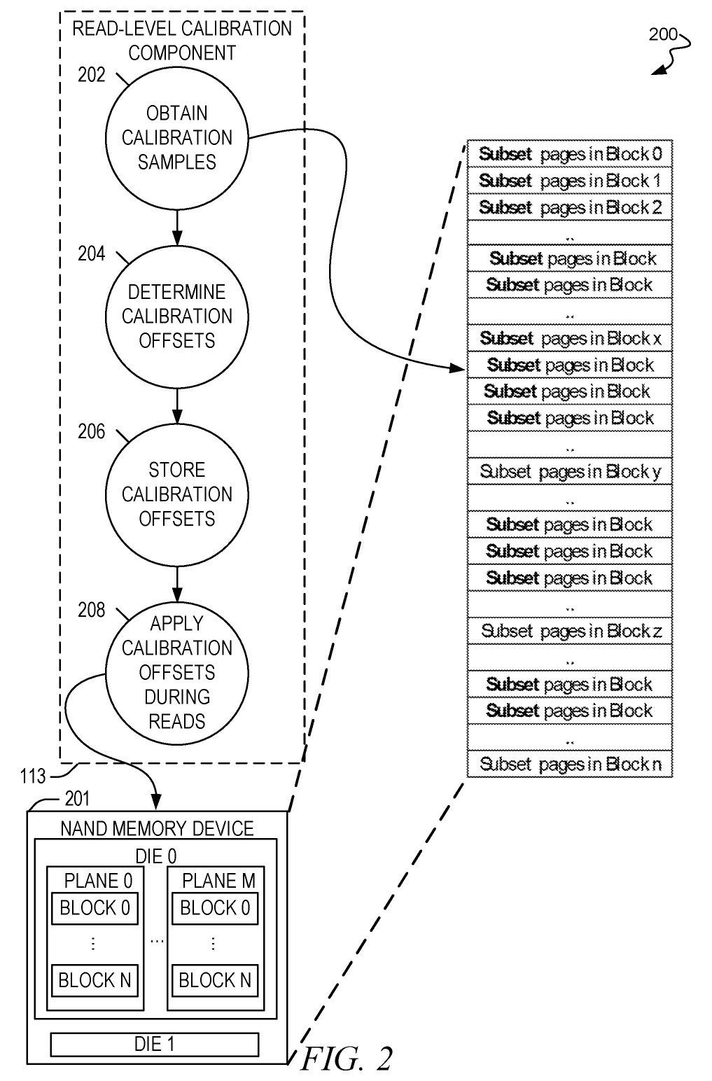

FIG. 2 is a data flow diagram illustrating interactions between components in the memory sub-system in performing a process 200 for read-level calibrations of a memory device 201, in accordance with some examples. In the example illustrated in FIG. 2, the memory device 201 is an example memory device 130 in the example form of a NAND memory device.

The memory device 201 includes multiple NAND dies. Each die may include one or more planes, and each plane includes multiple blocks such as block₀-block_{N} illustrated in FIG. 2. Each block includes a two- or three-dimensional array that includes pages (rows) and strings (columns). Pages in each block of the memory device 201 can be organized into multiple wordline groups. A string includes a plurality of memory cells connected in series. Each memory cell is used to represent one or more bit values. For example, a single NAND flash cell includes a transistor that stores an electric charge on a memory layer that is isolated by oxide insulating layers above and below. Within each cell, data is stored as the threshold voltage of the transistor. SLC NAND, for example, can store one bit per cell. Other types of memory cells, such as MLCs, TLCs, QLCs, and PLCs, can store multiple bits per cell.

As noted above, each NAND cell stores data in the form of the threshold voltage (V_{T}) of the transistor. The range of threshold voltages of a memory cell can be divided into a number of regions based on the number of bits stored by the cell where each region corresponds to a value that can be represented by the cell. More specifically, each region corresponds to a read voltage level (also referred to simply as “read-level”) and each read voltage level decodes into a multi-bit value. For example, a TLC NAND flash cell can be at one of eight read-levels (L0, L1, L2, L3, L4, L5, L6, or L7) and each read-level decodes into a 3-bit value that is stored in the flash cell (e.g., 111, 110, 100, 000, 010, 011, 001, and 101). Generally, to read data from a memory cell, one or more read-level voltages are applied to the gate of a transistor (of the memory cell) to determine (e.g., sense) the value of the current threshold voltage (e.g., the voltage at which the transistor conducts current), and the current threshold voltage value can be decoded (e.g., mapped) to a data value (e.g., bit string) stored by the memory cell. Vt variations due to various factors such as word line-to-word line (WL/WL) variations and block-to-block variations can lead to read errors and performance degradation. Hence, the read-level calibration component 113 performs read-level calibration of the memory device to mitigate against such read errors and performance degradation.

As shown, at operation 202, the read-level calibration component 113 obtains calibration samples for each block from a subset of pages of each block (where the subset includes fewer pages than the total number of pages in each block). That is, the read-level calibration component 113 obtains calibration samples for block₀ from a subset of pages of block₀, the read-level calibration component 113 obtains calibration samples for block₁ from a subset of pages of block₁, the read-level calibration component 113 obtains calibration samples for block₂ from a subset of pages of block₂, and so forth, as shown. The read-level calibration component 113 may, in some examples, perform one or more calibration reads on each of the subset of pages in each block to obtain calibration samples. In some examples, obtaining the calibration samples comprises issuing one or more commands to the memory device 201.

In some examples, the number of pages in each subset is a configurable parameter than can be adjusted based on input from the host system 120 to tune performance characteristics of the memory device 201. In some examples, the read-level calibration component 113 selects the subset of pages for each block based on one or more performance metrics and the performance characteristics of each page (e.g., based on tracked historical performance). In some examples, the read-level calibration component 113 selects at least one page from each wordline group to be included in the subset of pages.

The read-level calibration component 113 determines, at operation 204, one or more calibration offsets for each block based on the calibration samples for each block. In an example, the read-level calibration component 113 determines a first calibration offset for a first block based on calibration samples obtained from a subset of the pages of the first block and determines a second calibration offset for a second block based on calibration samples obtained from a subset of pages of the second block. In some examples, the read-level calibration component 113 determines multiple calibration offsets for each block, and each calibration offset corresponds to a particular group of pages. In a more specific example, the read-level calibration component 113 determines a calibration offset for each wordline group in a block based on one or more calibration samples from at least one page in each respective wordline group.

In general, calibration offsets are determined by analyzing voltage distributions between programmed states to determine appropriate read-level positions between these distributions based on the sampled pages and determining a calibration offset that, when applied to a read-level voltage, results in the appropriate read-level position. In some examples, the calibration samples obtained from the memory device 201 include calibration offsets or other intermediate values from which the read-level calibration component 113 can derive calibration offsets such as an optimal read-level.

In some examples, obtaining the calibration samples includes reading data from the memory device 201 (e.g., reading data from a sub-set of pages of each block) and determining calibration offsets based on the read data using one or more known techniques for determining calibration offsets. In an example, the read-level calibration component 113 may determine a calibration offset based on a bit error rate determined based on data read from the memory device 201. As another example, the read-level calibration component 113 may determine a calibration offset based on a read-level shift (e.g., a shift of read-level 7) determined based on data read from the memory device 201.

At operation 206, the read-level calibration component 113 stores the determined calibration offsets in local memory 119 or a dedicated portion of the memory device 201. The read-level calibration component 113 stores the calibration offsets in a table or other such data structure to facilitate the application of the appropriate calibration offset during read operations. That is, each calibration offset is stored with an association to the corresponding block and/or group of pages (e.g., wordline group) such that when a host read operation directed to a particular block or group of pages is received, the appropriate calibration offset can be quickly determined from the stored information. As an example, the calibration offsets may be stored in a table that maps specific pages or groups of pages of the memory device 201 to one or more calibration offsets.

The read-level calibration component 113 applies the calibration offsets during read operations (operation 208). More specifically, the read-level calibration component 113 applies calibration offsets to a read voltage during read operations. In an example, a host read command directed at a first block is received, the read-level calibration component 113 determines a calibration offset for the read command based on stored calibration offsets for the block, and applies the calibration offset to a read voltage during the read operation on the block. In a more specific example, the read-level calibration component 113 determines, based on stored information, a calibration offset for a group of pages (e.g., a wordline group) based on the read command being directed at one or more pages in the group of pages, and the read-level calibration component 113 applies the calibration offset to the read voltage during a read operation on the one or more pages.

In some examples, upon detecting a recalibration triggering event (e.g., a transition between host reads on different blocks), the read-level calibration component 113 may recalibrate read-levels for any one or more of the blocks of the memory device 201. That is, the read-level calibration component 113 may obtain additional samples for a block and update the one or more calibration offsets for the block based on the additional samples, in response to detecting a recalibration triggering event.

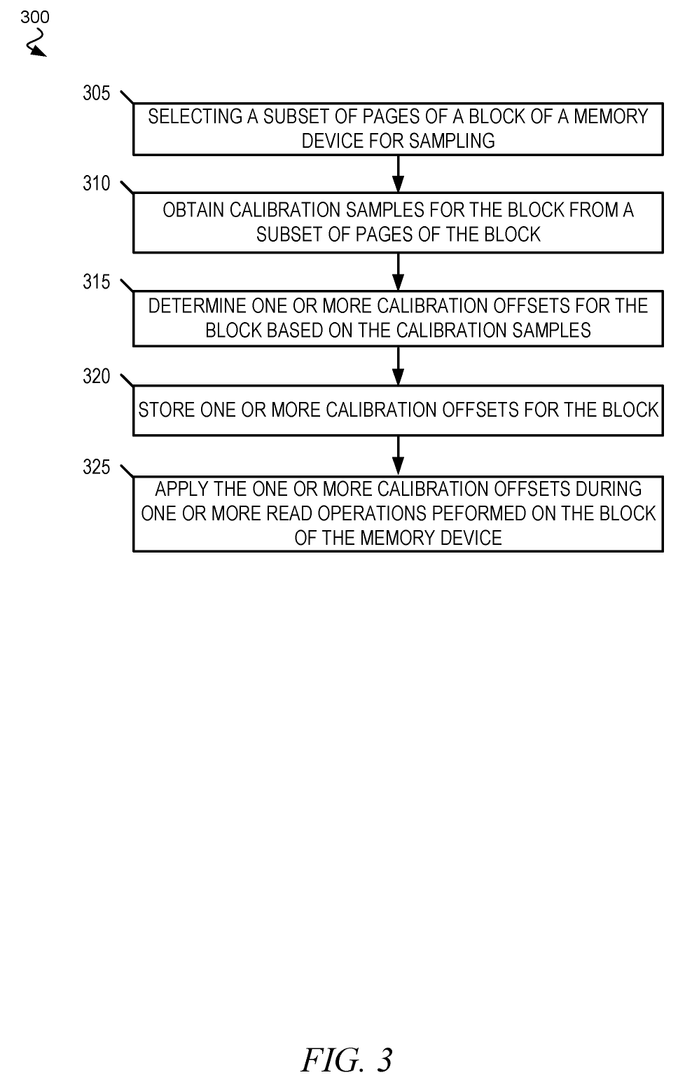

FIG. 3 is a flow diagram illustrating an example method 300 for performing read-level calibrations on a memory device, in accordance with some examples. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 300 is performed by the read-level calibration component 113 of FIG. 1. Although processes are shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment; other process flows are possible.

At operation 305, the processing device selects a subset of pages of a block of a memory device to sample for aiding in read-level calibration of the block. That is, the memory device comprises a set of pages, and the processing device selects a subset of pages from the set of pages. In some examples, pages within each block of the memory device are organized into multiple wordline groups, and consistent with these examples, the processing device may select a page from each wordline group of the block. In some examples, the processing device tracks the performance of the pages of the block and maintains a look-up table that identifies which pages should be included in the sampling subset based on the performance characteristics of each page. Consistent with these examples, the processing device can identify the subset of pages based on a comparison of one or more performance metrics and performance characteristics of the pages in the block.

In an example, the number of pages in the subset of pages is fewer than the number of pages in the set of pages of the block. In some examples, the number of pages in the subset of pages is a configurable parameter that can be adjusted. Consistent with these examples, the processing device can adjust the number of pages in the subset of pages based on input (e.g., one or more commands) received from the host system.

At operation 310, the processing device obtains calibration samples for the block from the subset of pages. To obtain the calibration samples, the processing device issues one or more commands to the memory device. In some examples, the processing device obtains the calibration samples by performing one or more calibration reads on the subset of pages. That is, in these examples, the processing device may read data stored by the subset of pages to obtain the calibration samples. In some examples, the calibration samples comprise a passing read voltage, and the obtaining of the calibration samples comprises determining a read voltage that results in successfully reading data from the subset of pages (the passing read voltage).

At operation 315, the processing device determines one or more calibration offsets for the block based on the calibration samples from the subset of pages. In general, calibration offsets are determined by analyzing voltage distributions between programmed states to determine appropriate read-level positions between these distributions based on the sampled pages.

In some examples, the calibration samples obtained from the memory device include calibration offsets or other intermediate values from which the read-level calibration offsets may be determined (e.g., via a look-up table that maps the intermediate values to calibration offsets). In some examples, obtaining the calibration samples includes reading data from the memory device (e.g., reading data from a sub-set of pages of each block) and determining calibration offsets based on the read data using one or more known techniques for determining calibration offsets. In some examples, the determining of the one or more calibration offsets comprises accessing a look-up table (e.g., comprising a mapping between calibration sample values and calibration offsets).

At operation 320, the processing device stores the one or more calibration offsets for the block for subsequent use in read operations directed at the block. The processing device may store the one or more calibration offsets in local memory (e.g., the local memory 119) or a dedicated portion of the memory device. The processing device stores the one or more calibration offsets in a table or other data structure with an association with the block such that when host read commands directed at the block are received, the processing device can determine the one or more calibrations for the block from the table or other data structure. In some examples, calibration offsets can be stored with an association with one or more specific sub-sets or groups of pages from the block. Consistent with these examples, the processing device can store a first calibration offset for a first wordline group in the block with an association with the first wordline group, store a second calibration offset for a second wordline group in the block with an association with the second wordline group, store a third calibration offset for a third wordline group in the block with an association with the third wordline group, and so forth.

At operation 325, the processing device applies the one or more calibration offsets during read operations directed at the block. Applying a calibration offset during a read operation comprises applying the calibration offset to a read voltage used to read data from the block during a read operation. As noted above, when a host read command directed at the block is received, the processing device can determine the appropriate calibration offset based on the one or more calibration offsets for the block stored at operation 320.

In an example, the determining of the one or more calibration offsets for the block comprises determining a first calibration offset for a first group of pages (e.g., a first wordline group) in the block based on a first set of calibration samples from a first subset of pages from the first group of pages and determining a second calibration offset for a second group of pages (e.g., a second wordline group) in the block based on a second set of calibration samples from a second subset of pages from the second group of pages.

Although FIG. 3 and the corresponding description presented above address only a single block of the memory device, it shall be appreciated that method 300 may be repeated for every block in the memory device. As an example, in a first iteration of the method 300, calibration offsets for a first block are determined from calibration samples from a subset of pages of the first block and applied during read operations on the first block and in second iteration of the method 300, calibration offsets for a second block are determined from calibration samples from a subset of pages of the second block and applied during read operations on the second block. Consistent with this example, multiple such iterations of the method 300 are performed until one or more calibration offsets are determined for every block in the memory device.

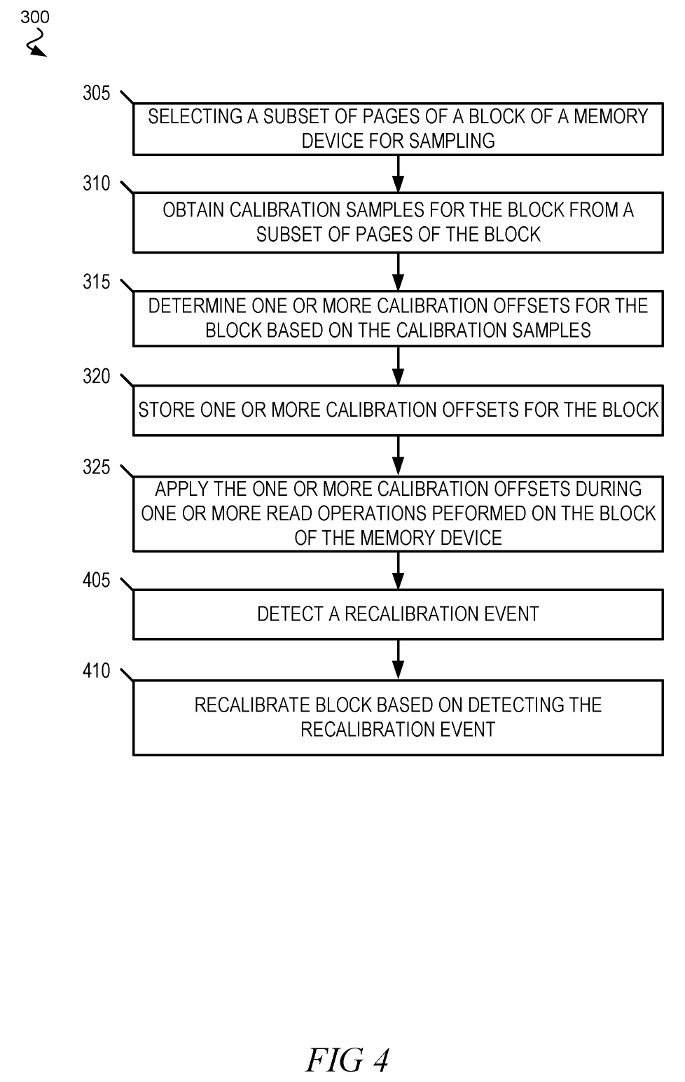

As shown in FIG. 4, the method 300 can, in some examples, further include operations 405 and 410. Though the operations 405 and 410 are illustrated as being performed subsequent to operation 325 where the processing device applies the calibration offsets, the operations 405 and 410 can be performed at any time subsequent to the operation 315 where the processing device determines the calibration offsets for the block.

As shown, the processing device detects a recalibration triggering event (at operation 405) and performs recalibration of the block based on the recalibration triggering event (at operation 410). The recalibration triggering event may, for example, correspond to host read operations jumping from one block to another block. In recalibrating the block, the processing device obtains additional calibration samples from the sub-set of pages of the block and determines one or more updated calibration offsets based on the additional calibration samples.

Described implementations of the subject matter can include one or more features, alone or in combination, as illustrated below by way of example.

Example 1. A memory sub-system comprising: a memory device comprising a set of blocks, a block in the set of blocks comprising a set of pages; a processing device, operatively coupled with the memory device, to perform operations comprising: obtaining calibration samples for the block from a subset of pages of the block; determining one or more calibration offsets for the block based on the calibration samples from the subset of pages of the block; and applying the one or more calibration offsets during one or more read operations performed on the block of the memory device.

Example 2. The memory sub-system of claim 1, wherein: the determining of the one or more calibration offsets for the block comprises: determining a first calibration offset for a first group of pages in the block based on a first set of calibration samples from a first subset of pages from the first group of pages; and determining a second calibration offset for a second group of pages in the block based on a second set of calibration samples from a second subset of pages from the second group of pages; and the applying of the one or more calibration offsets comprises: applying the first calibration offset during read operations performed on the first group of pages; and applying the second calibration offset during read operations performed on the second group of pages.

Example 3. The memory sub-system of claim 2, wherein: the block is a first block; the one or more calibration offsets are a first set of calibration offsets; the operations comprise: obtaining calibration samples for a second block from a subset of pages of the second block; determining a second set of calibration offsets for the second block based on the calibration samples from the subset of pages of the second block; and applying the second set of calibration offsets during one or more read operations performed on the second block of the memory device.

Example 4. The memory sub-system of claim 1, wherein the operations comprise storing the one or more calibration offsets for the block in the memory device or local memory of the processing device.

Example 5. The memory sub-system of claim 1, wherein operations comprise selecting the subset of pages from the block based on one or more performance characteristics of the subset of pages.

Example 6. The memory sub-system of claim 5, wherein: the set of pages of the block are organized into multiple wordline groups; and the selecting of the subset of pages comprises selecting at least one page from each wordline group of the multiple wordline groups.

Example 7. The memory sub-system of claim 1, wherein the operations comprise: detecting a recalibration triggering event; and based on the recalibration triggering event, performing recalibration of read-levels of the block, the performing of read-level calibration comprising: obtaining additional calibration samples for the block from the subset of pages of the block; determining one or more updated calibration offsets for the block based on the additional calibration samples from the subset of pages of the block; and storing the one or more updated calibration offsets for the block.

Example 8. The memory sub-system of claim 7, wherein detecting the recalibration triggering event comprises detecting a transition between blocks during read operations.

Example 9. The memory sub-system of claim 1, wherein applying the one or more calibration offsets during one or more read operations performed on the block comprises applying a calibration offset to a read voltage during a read operation performed on the block.

Example 10. The memory sub-system of claim 1, wherein the subset of pages comprises a configurable number of pages.

Example 11. The memory sub-system of claim 1, wherein the subset of pages of the block comprises fewer pages than the set of pages of the block.

Example 12. A method comprising: obtaining, by a processing device, calibration samples for a block of a memory device from a subset of pages of the block; determining, by the processing device, one or more calibration offsets for the block based on the calibration samples from the subset of pages of the block; storing the one or more calibration offsets for the block; and applying, by the processing device, the one or more calibration offsets during one or more read operations performed on the block of the memory device.

Example 13. The method of claim 12, wherein: the determining of the one or more calibration offsets for the block comprises: determining a first calibration offset for a first group of pages in the block based on a first set of calibration samples from a first subset of pages from the first group of pages; and determining a second calibration offset for a second group of pages in the block based on a second set of calibration samples from a second subset of pages from the second group of pages; and the applying of the one or more calibration offsets comprises: applying the first calibration offset during read operations performed on the first group of pages; and applying the second calibration offset during read operations performed on the second group of pages.

Example 14. The method of claim 13, wherein: the block is a first block; the one or more calibration offsets are a first set of calibration offsets; the operations comprise: obtaining calibration samples for a second block from a subset of pages of the second block; determining a second set of calibration offsets for the second block based on the calibration samples from the subset of pages of the second block; and applying the second set of calibration offsets during one or more read operations performed on the second block of the memory device.

Example 15. The method of claim 12, wherein the storing of the one or more calibration offsets for the block comprises storing the one or more calibration offsets in the memory device or local memory of the processing device.

Example 16. The method of claim 12, wherein operations comprise selecting the subset of pages from the block based on one or more performance characteristics of the subset of pages.

Example 17. The method of claim 16, wherein: pages of the block are organized into multiple wordline groups; and the selecting of the subset of pages comprises selecting at least one page from each wordline group of the multiple wordline groups.

Example 18. The method of claim 12, comprising: detecting a recalibration triggering event; and based on the recalibration triggering event, performing recalibration of read-levels of the block, the performing of read-level calibration comprising: obtaining additional calibration samples for the block from the subset of pages of the block; determining one or more updated calibration offsets for the block based on the additional calibration samples from the subset of pages of the block; and storing the one or more updated calibration offsets for the block.

Example 19. The method of claim 18, wherein detecting the recalibration triggering event comprises detecting a transition between blocks during read operations.

Example 20. A computer-readable storage medium comprising instructions that, when executed by a processing device, configure the processing device to perform operations comprising: selecting a subset of pages of a block of a memory device for sampling; obtaining calibration samples for the block from the subset of pages of the block; determining one or more calibration offsets for the block based on the calibration samples from the subset of pages of the block; and applying the one or more calibration offsets during one or more read operations performed on the block of the memory device.

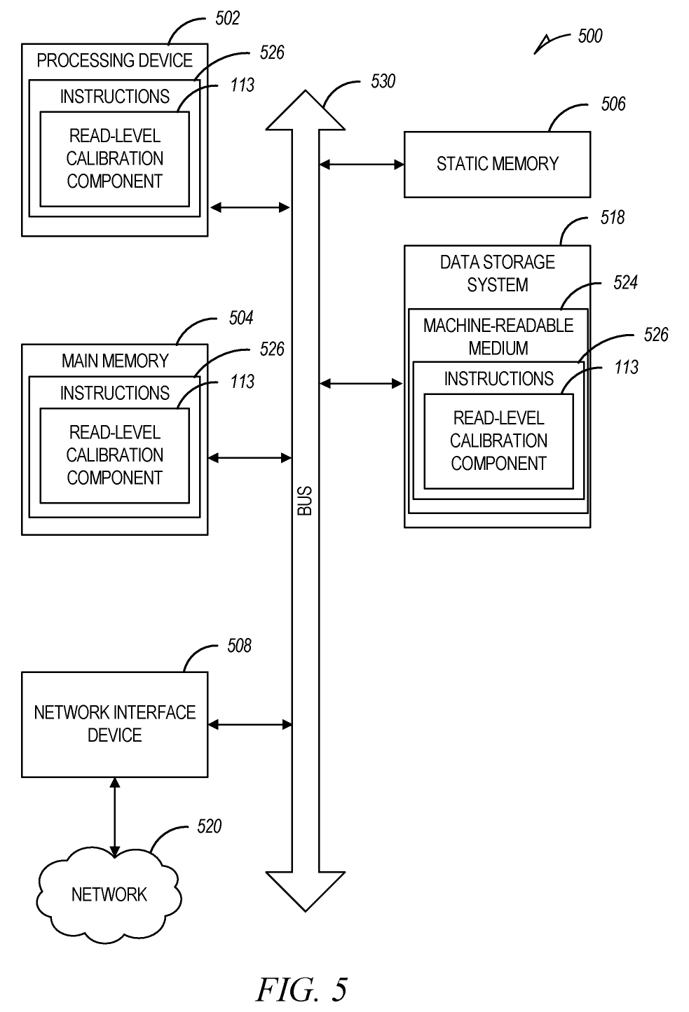

FIG. 5 illustrates an example machine in the form of a computer system within which a set of instructions can be executed for causing the machine to perform any one or more of the methodologies discussed herein. FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the read-level calibration component 113 of FIG. 1). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or RDRAM, etc.), a static memory 506 (e.g., flash memory, static random-access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an ASIC, a FPGA, a digital signal processor (DSP), network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a read-level calibration component (e.g., the read-level calibration component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader scope of embodiments of the disclosure as set forth in the following claims. The specification and drawings are, accordingly, to be regarded in an illustrative sense rather than a restrictive sense.

What is claimed is:

1. A memory sub-system comprising:
a memory device comprising a set of blocks, a block in the set of blocks comprising a set of pages;
a processing device, operatively coupled with the memory device, to perform operations comprising:
obtaining calibration samples for the block from a subset of pages of the block;
determining one or more calibration offsets for the block based on the calibration samples from the subset of pages of the block; and
applying the one or more calibration offsets during one or more read operations performed on the block of the memory device.

2. The memory sub-system of claim 1, wherein:
the determining of the one or more calibration offsets for the block comprises:
determining a first calibration offset for a first group of pages in the block based on a first set of calibration samples from a first subset of pages from the first group of pages; and
determining a second calibration offset for a second group of pages in the block based on a second set of calibration samples from a second subset of pages from the second group of pages; and
the applying of the one or more calibration offsets comprises:
applying the first calibration offset during read operations performed on the first group of pages; and
applying the second calibration offset during read operations performed on the second group of pages.

3. The memory sub-system of claim 2, wherein:
the block is a first block;
the one or more calibration offsets are a first set of calibration offsets;
the operations comprise:
obtaining calibration samples for a second block from a subset of pages of the second block;
determining a second set of calibration offsets for the second block based on the calibration samples from the subset of pages of the second block; and
applying the second set of calibration offsets during one or more read operations performed on the second block of the memory device.

4. The memory sub-system of claim 1, wherein the operations comprise storing the one or more calibration offsets for the block in the memory device or local memory of the processing device.

5. The memory sub-system of claim 1, wherein operations comprise selecting the subset of pages from the block based on one or more performance characteristics of the subset of pages.

6. The memory sub-system of claim 5, wherein:
the set of pages of the block are organized into multiple wordline groups; and
the selecting of the subset of pages comprises selecting at least one page from each wordline group of the multiple wordline groups.

7. The memory sub-system of claim 1, wherein the operations comprise:
detecting a recalibration triggering event; and
based on the recalibration triggering event, performing recalibration of read-levels of the block, the performing of read-level calibration comprising:
obtaining additional calibration samples for the block from the subset of pages of the block;
determining one or more updated calibration offsets for the block based on the additional calibration samples from the subset of pages of the block; and
storing the one or more updated calibration offsets for the block.

8. The memory sub-system of claim 7, wherein detecting the recalibration triggering event comprises detecting a transition between blocks during read operations.

9. The memory sub-system of claim 1, wherein applying the one or more calibration offsets during one or more read operations performed on the block comprises applying a calibration offset to a read voltage during a read operation performed on the block.

10. The memory sub-system of claim 1, wherein the subset of pages comprises a configurable number of pages.

11. The memory sub-system of claim 1, wherein the subset of pages of the block comprises fewer pages than the set of pages of the block.

12. A method comprising:
obtaining, by a processing device, calibration samples for a block of a memory device from a subset of pages of the block;
determining, by the processing device, one or more calibration offsets for the block based on the calibration samples from the subset of pages of the block;
storing the one or more calibration offsets for the block; and
applying, by the processing device, the one or more calibration offsets during one or more read operations performed on the block of the memory device.

13. The method of claim 12, wherein:
the determining of the one or more calibration offsets for the block comprises:
determining a first calibration offset for a first group of pages in the block based on a first set of calibration samples from a first subset of pages from the first group of pages; and
determining a second calibration offset for a second group of pages in the block based on a second set of calibration samples from a second subset of pages from the second group of pages; and
the applying of the one or more calibration offsets comprises:
applying the first calibration offset during read operations performed on the first group of pages; and
applying the second calibration offset during read operations performed on the second group of pages.

14. The method of claim 13, wherein:
the block is a first block;
the one or more calibration offsets are a first set of calibration offsets;
the operations comprise:
obtaining calibration samples for a second block from a subset of pages of the second block;
determining a second set of calibration offsets for the second block based on the calibration samples from the subset of pages of the second block; and
applying the second set of calibration offsets during one or more read operations performed on the second block of the memory device.

15. The method of claim 12, wherein the storing of the one or more calibration offsets for the block comprises storing the one or more calibration offsets in the memory device or local memory of the processing device.

16. The method of claim 12, wherein operations comprise selecting the subset of pages from the block based on one or more performance characteristics of the subset of pages.

17. The method of claim 16, wherein:
pages of the block are organized into multiple wordline groups; and
the selecting of the subset of pages comprises selecting at least one page from each wordline group of the multiple wordline groups.

18. The method of claim 12, comprising:
detecting a recalibration triggering event; and
based on the recalibration triggering event, performing recalibration of read-levels of the block, the performing of read-level calibration comprising:
obtaining additional calibration samples for the block from the subset of pages of the block;
determining one or more updated calibration offsets for the block based on the additional calibration samples from the subset of pages of the block; and
storing the one or more updated calibration offsets for the block.

19. The method of claim 18, wherein detecting the recalibration triggering event comprises detecting a transition between blocks during read operations.

20. A computer-readable storage medium comprising instructions that, when executed by a processing device, configure the processing device to perform operations comprising:
selecting a subset of pages of a block of a memory device for sampling;
obtaining calibration samples for the block from the subset of pages of the block;
determining one or more calibration offsets for the block based on the calibration samples from the subset of pages of the block; and
applying the one or more calibration offsets during one or more read operations performed on the block of the memory device.
